(19) United States
(12) Patent Application Publication
(10) Pub. No.: US 2026/0190252 A1
(43) Pub. Date: Jul. 2, 2026

(54) ELECTRONIC DEVICE

(71) Applicant: Samsung Display Co., Ltd., Yongin-si (KR)

(72) Inventors: Wonseok Kim, Yongin-si (KR); Jeongin Lee, Yongin-si (KR); Jinyeong Heo, Yongin-si (KR)

(21) Appl. No.: 19/285,825

(22) Filed: Jul. 30, 2025

(30) Foreign Application Priority Data
Dec. 30, 2024 (KR) 10-2024-0201168

(51) Int. Cl. H05K 5/02

(52) U.S. Cl. CPC H05K 5/0217

(57) ABSTRACT

An electronic device includes: a display panel comprising a first area, a second area, and a bending area between the first area and the second area, the bending area being bendable and having a shape extending in a second direction intersecting a first imaginary straight line extending in a first direction connecting the first area and the second area to each other; and a support portion located at a back of the display panel, and comprising a first support portion supporting the first area and comprising a first material, a second support portion supporting the second area and comprising the first material, and an elastic support portion supporting at least a portion of the bending area and comprising a second material having elasticity greater than elasticity of the first material.

### CROSS-REFERENCE TO RELATED APPLICATION

The present application claims priority to and the benefit of Korean Patent Application No. 10-2024-0201168, filed on Dec. 30, 2024, in the Korean Intellectual Property Office, the entire disclosure of which is incorporated herein by reference.

### BACKGROUND

### 1. Field

Aspects of some embodiments of the present disclosure relate to an electronic device.

### 2. Description of the Related Art

An electronic device may include a display panel as an input means or an output means. For example, the electronic device may be a mobile electronic device such as a smartphone. Such an electronic device may be a foldable electronic device in which some components, such as a display panel, are configured to be folded in a bending area, without damaging the electronic device, in order to relatively increase the area of a display surface while relatively reducing the overall size of the electronic device.

The above information disclosed in this Background section is only for enhancement of understanding of the background and therefore the information discussed in this Background section does not necessarily constitute prior art.

### SUMMARY

Aspects of some embodiments of the present disclosure relate to an electronic device and, for example, to an electronic device having relatively excellent impact resistance against external impacts.

Some electronic devices may have a problem in that damage may occur in a bending area while being used by a user.

One or more embodiments include an electronic device having relatively excellent impact resistance against external impacts. However, the one or more embodiments are only examples, and the scope of embodiments according to the present disclosure are not limited thereby.

Additional aspects will be set forth in part in the description which follows and, in part, will be apparent from the description, or may be learned by practice of the presented embodiments of the disclosure.

According to one or more embodiments, an electronic device includes a display panel including a first area, a second area, and a bending area between the first area and the second area, the bending area being bendable and having a shape extending in a second direction intersecting a first imaginary straight line extending in a first direction connecting the first area and the second area to each other, and a support portion located at a back of the display panel, and including a first support portion supporting the first area and including a first material, a second support portion supporting the second area and including the first material, and an elastic support portion supporting at least a portion of the bending area and including a second material having elasticity greater than elasticity of the first material.

According to some embodiments, the elastic support portion may connect the first support portion and the second support portion to each other.

According to some embodiments, in a plan view, an area of the elastic support portion may be greater than an area of the bending area.

According to some embodiments, in a plan view, the bending area may be within the elastic support portion.

According to some embodiments, in a plan view, the elastic support portion may have a plurality of first protrusions protruding into the first support portion and a plurality of second protrusions protruding into the second support portion.

According to some embodiments, in the plan view, each of the plurality of first protrusions may include a first-1 portion having a first width and a first-2 portion having a second width greater than the first width, and the first-2 portion may be located farther from a center of the elastic support portion than the first-1 portion.

According to some embodiments, in the plan view, each of the plurality of second protrusions may include a second-1 portion having a first width and a second-2 portion having a second width greater than the first width, and the second-2 portion may be located farther from a center of the elastic support portion than the second-1 portion.

According to some embodiments, the plurality of first protrusions and the plurality of second protrusions may be alternately arranged in the second direction.

According to some embodiments, the elastic support portion may include a first elastic support portion in contact with the first support portion, and a second elastic support portion in contact with the second support portion, and the support portion may further include an auxiliary support portion including the first material and arranged between the first elastic support portion and the second elastic support portion.

According to some embodiments, the auxiliary support portion may be in contact with each of the first elastic support portion and the second elastic support portion.

According to some embodiments, in a plan view, a boundary between the first area and the bending area may be within the first elastic support portion, and a boundary between the second area and the bending area may be within the second elastic support portion.

According to some embodiments, the electronic device may further include an additional support portion arranged between the display panel and the support portion.

According to some embodiments, the additional support portion may entirely cover a bottom surface of the display panel.

According to some embodiments, the elastic support portion and the additional support portion may be integrally formed as a single body.

According to some embodiments, the first material may include metal, carbon fiber-reinforced plastic (CFRP), or glass fiber-reinforced plastic (GFRP).

According to some embodiments, the second material may include rubber resin, silicone resin, or thermoplastic polyurethane (TPU).

According to some embodiments, the electronic device may be one of a flat panel display, a curved display, a computer monitor, a medical monitor, a television, an advertisement board, an indoor light, an outdoor light, and/or a signal light, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual reality display, an augmented reality display, a vehicle, a video wall including multiple displays tiled together, a theater screen, a stadium screen, a phototherapy device, and a signboard.

Other aspects, features, and characteristics than those described above will become apparent from the following drawings, claims, and detailed descriptions to embody the disclosure below.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a perspective view schematically illustrating a portion of an electronic device according to some embodiments;

FIG. 2 is a cross-sectional view schematically illustrating a portion of the electronic device of FIG. 1;

FIG. 3 is a cross-sectional view schematically illustrating the electronic device of FIG. 2 when bent;

FIG. 4 is a plan view schematically illustrating a portion of an electronic device according to some embodiments;

FIG. 5 is a plan view schematically illustrating a portion of an electronic device according to some embodiments;

FIG. 6 is a plan view schematically illustrating a portion of an electronic device according to some embodiments;

FIG. 7 is a cross-sectional view schematically illustrating a portion of an electronic device according to some embodiments;

FIG. 8 is a cross-sectional view schematically illustrating a portion of an electronic device according to some embodiments;

FIG. 9 is a cross-sectional view schematically illustrating a portion of an electronic device according to some embodiments;

FIG. 10 is a block diagram schematically illustrating an electronic device according to some embodiments;

FIG. 11 shows schematic views schematically illustrating electronic devices according to some embodiments;

FIG. 12 is a schematic view schematically illustrating a case in which electronic devices according to some embodiments are wearable electronic devices; and

FIG. 13 is a schematic view schematically illustrating a case in which an electronic device according to some embodiments is a vehicle electronic device.

### DETAILED DESCRIPTION

Reference will now be made in more detail to aspects of some embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the disclosure, and a method to achieve the same, will be clearer referring to the detailed descriptions below with the drawings. However, the present embodiments may be implemented in various forms, not by being limited to the embodiments presented below.

Hereinafter, aspects of some embodiments will be described in more detail with reference to the accompanying drawings, and in the description with reference to the drawings, the same or corresponding elements are indicated by the same reference numerals and some redundant descriptions thereof may be omitted.

In the following embodiments, it will be understood that when a component such as a layer, film, area, or plate is referred to as being “formed on” another layer, film, area, or plate, it can be directly or indirectly formed on the other layer, film, area, or plate. That is, for example, intervening layers, films, areas, or plates may be present. Also, sizes of components in the drawings may be exaggerated for convenience of explanation. In other words, because sizes and thicknesses of some elements in the drawings may be arbitrarily illustrated for convenience of explanation, the following embodiments are not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the following embodiments, it will be understood that although the terms “first,” “second,” etc. may be used herein to describe various components, these components should not be limited by these terms. These terms are only used to distinguish one component from another.

In the following embodiments, it will be further understood that the terms “comprises” and/or “comprising” used herein specify the presence of stated features or components, but do not preclude the presence or addition of one or more other features or components.

In the present specification, the expression “A and/or B” represents A, B, or A and B. In addition, the expression “at least one of A and B” represents A, B, or A and B.

It will be understood that when a layer, area, or component is referred to as being “connected to” another layer, area, or component, it can be directly or indirectly connected to the other layer, area, or component. That is, for example, intervening layers, areas, or components may be present. For example, in the present specification, when a layer, area, or component is electrically connected to another layer, area, or component, the layers, areas, or components may not only be directly electrically connected, but may also be indirectly electrically connected via another layer, area, or component therebetween.

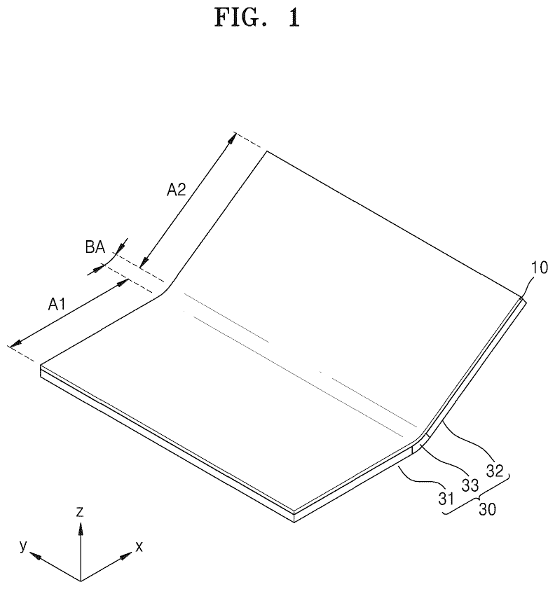

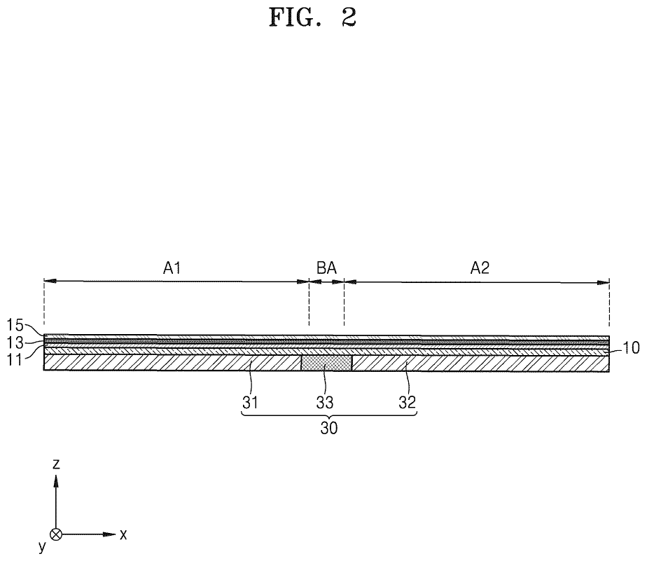

FIG. 1 is a perspective view schematically illustrating a portion of an electronic device according to some embodiments, and FIG. 2 is a cross-sectional view schematically illustrating a portion of the electronic device of FIG. 1. For reference, FIG. 1 illustrates that a display panel 10 and the like are slightly bent in some parts, and FIG. 2 illustrates that the display panel 10 and the like are not bent and are in an overall flat state.

The electronic device according to some embodiments is an device that displays a moving image or a still image and may be not only a portable electronic device, such as a mobile phone, a smartphone, a tablet personal computer (PC), a mobile communication terminal, an electronic notebook, an e-book, a portable multimedia player (PMP), a navigation device, or an ultra-mobile PC, but also various products, such as a television, a laptop, a monitor, a billboard, or an Internet of things (IoT) device, or a part thereof. In addition, the electronic device according to some embodiments may be a wearable device, such as a smart watch, a watch phone, a glasses-type display, or a head-mounted display (HMD), or may be a part thereof. Embodiments according to the present disclosure are not limited thereto. For example, the electronic device according to some embodiments may be, as necessary, an instrument panel of a vehicle, a center information display (CID) arranged on a center fascia or dashboard of a vehicle, a room mirror display in lieu of a side-view mirror of a vehicle, a display that is for a rear seat of a vehicle or arranged at the back of a front seat, a head up display (HUD) installed at the front of a vehicle or projected onto a front window glass, or a computer-generated hologram augmented reality (CGH AR) HUD. For convenience of explanation, FIGS. 1 and 2 illustrate a case in which the electronic device is a smartphone or a tablet PC.

The electronic device according to some embodiments may include the display panel 10 and a support portion 30.

The display panel 10 may display images. To this end, the display panel 10 may include a substrate and display elements, such as an organic light-emitting element, arranged on the substrate. FIG. 1 illustrates that a top surface (a surface in a +z (or an approximately +z) direction) of the display panel 10 is a display surface.

The display panel 10 may include a first area A1, a second area A2, and a bending area BA. The bending area BA may be arranged between the first area A1 and the second area A2. In a state where the display panel 10 is unfolded without being bent, the bending area BA may have a shape extending in a second direction (a y-axis direction) intersecting a first imaginary straight line extending in a first direction (an x-axis direction) connecting the first area A1 and the second area A2 to each other. The display panel 10 may be bent at the bending area BA. After being bent at the bending area BA, the display panel 10 may return to a non-bending state. In other words, the display panel 10 is a foldable display panel.

The display panel 10 has foldable characteristics, and thus, the substrate included in the display panel 10 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate included in the display panel 10 may have a multilayer structure including two layers including polymer resin and a barrier layer arranged between the two layers and including an inorganic material, and may be modified in various ways. In this case, the barrier layer may include silicon oxide, silicon nitride, or silicon oxynitride.

Various display elements may be arranged on the substrate. For example, organic light-emitting elements including pixel electrodes, a common electrode as a single body corresponding to the pixel electrodes, and an intermediate layer arranged between the pixel electrodes and the common electrode and including at least emission layers may be arranged on the substrate. Thin-film transistors, a capacitor, and the like, which are for controlling an electrical signal to be applied to the organic light-emitting elements, may also be arranged on the substrate.

The display panel 10 may display images in the first area A1, the second area A2, and the bending area BA. In other words, a display area of the first area A1, a display area of the second area A2, and a display area of the bending area BA may be connected to each other as a single body.

The support portion 30 may be arranged at the back of the display panel 10. In other words, as shown in FIG. 2, the display panel 10 has a front surface (in the +z direction) and a rear surface (in a −z direction) opposite to the front surface, wherein the front surface may include a display surface. The support portion 30 may be arranged at the back of the display panel 10 to face the rear surface of the display panel 10. A pressure-sensitive adhesive (PSA) layer may be arranged between the support portion 30 and the display panel 10, enabling the support portion 30 and the display panel 10 to be bonded to each other.

The support portion 30 may include a first support portion 31, a second support portion 32, and an elastic support portion 33. The first support portion 31 may support the first area A1 of the display panel 10. The second support portion 32 may support the second area A2 of the display panel 10. The elastic support portion 33 may support at least a portion of the bending area BA of the display panel 10. For example, as shown in FIG. 2, the elastic support portion 33 may connect the first support portion 31 and the second support portion 32 to each other and support the bending area BA of the display panel 10.

The first support portion 31 and the second support portion 32, each including a first material, may support the display panel 10 as a whole. As described above, the display panel 10 may be bent at the bending area BA. However, the display panel 10 may basically have the same (or substantially the same) structure in the first area A1, the second area A2, and the bending area BA. Therefore, the display panel 10 may theoretically have a structure that may be bent not only in the bending area BA but also in the first area A1 or the second area A2. The first support portion 31 and the second support portion 32 may support the first area A1 and the second area A2 of the display panel 10, thereby preventing, reducing, or minimizing bending of the display panel 10 in the first area A1 and the second area A2. To this end, the first support portion 31 and the second support portion 32 may have a rigidity that prevents or reduces bending.

Herein, when the first support portion 31 supports the first area A1 of the display panel 10, it means that when viewed in a direction (for example, an z-axis direction of FIG. 2) perpendicular to the front surface of the first area A1 of the display panel 10, in other words, in a plan view, the first support portion 31 and the first area A1 of the display panel 10 overlap each other. FIG. 2 illustrates that the area of a surface of the first support portion 31, facing the display panel 10, is narrower than the area of the first area A1 of the display panel 10. However, even so, the area of the surface the first support portion 31 is sufficient as long as the first support portion 31 is able to support the first area A1 of the display panel 10 as a whole.

Likewise, when the second support portion 32 supports the second area A2 of the display panel 10, it means that when viewed in a direction (for example, the z-axis direction of FIG. 2) perpendicular to the front surface of the second area A2 of the display panel 10, in other words, in a plan view, the second support portion 32 and the second area A2 of the display panel 10 overlap each other. FIG. 2 illustrates that the area of a surface of the second support portion 32, facing the display panel 10, is narrower than the area of the second area A2 of the display panel 10. However, even so, the area of the surface of the second support portion 32 is sufficient as long as the second support portion 32 is able to support the second area A2 of the display panel 10.

Both the first support portion 31 and the second support portion 32 may include the first material, wherein the first material may include metal, carbon fiber-reinforced plastic (CFRP), or glass fiber-reinforced plastic (GFRP). As described above, the first support portion 31 and the second support portion 32, each including the first material, may support the first area A1 and the second area A2 of the display panel 10, thereby preventing, reducing, or minimizing bending of the display panel 10 in the first area A1 and the second area A2.

The elastic support portion 33 may connect the first support portion 31 and the second support portion 32 to each other while supporting at least a portion of the bending area BA of the display panel 10. FIG. 2 illustrates that the elastic support portion 33 supports the entire bending area BA.

When the elastic support portion 33 supports the bending area BA of the display panel 10, it means that, as shown in FIG. 2, in a case where the display panel 10 is in a non-bending state, when viewed in a direction (for example, the z-axis direction of FIG. 2) perpendicular to the front surface of the bending area BA of the display panel 10, in other words, in a plan view, the elastic support portion 33 and the bending area BA of the display panel 10 overlap each other. FIG. 2 illustrates that the elastic support portion 33 supports the entire bending area BA of the display panel 10 because the area of a surface of the elastic support portion 33, facing the display panel 10, is larger than the area of the bending area BA of the display panel 10. In other words, FIG. 2 illustrates that the bending area BA of the display panel 10 is within the elastic support portion 33 in a plan view.

In order for the electronic device to have bendable characteristics, when the display panel 10 is bent at the bending area BA, the elastic support portion 33 is required to be bent together with the bending area BA of the display panel 10. To this end, the physical characteristics of the elastic support portion 33 itself may be different from the physical characteristics of the first support portion 31 or the physical characteristics of the second support portion 32. For example, the overall rigidity of the elastic support portion 33 may be lower than the overall rigidity of the first support portion 31 or the overall rigidity of the second support portion 32. In other words, the elastic support portion 33 itself may have flexible characteristics. To this end, the elastic support portion 33 may include a second material having elasticity greater than the elasticity of the first material included in the first support portion 31 and the second support portion 32. The second material may include rubber resin, silicone resin, or thermoplastic polyurethane (TPU).

In the case of the electronic device according to the present embodiments, not only the first area A1 and the second area A2 of the display panel 10 but also the bending area BA may be supported by the support portion 30. Therefore, even when the bending area BA of the display panel 10 is touched using a tool such as a stylus pen or a user's finger while the user uses the electronic device, and repeated impacts are applied to the bending area BA of the display panel 10, the bending area BA of the display panel 10 may be sufficiently supported by the elastic support portion 33.

For reference, a case may be considered where the support portion 30 does not have the structure described above but does include the first material across the entire first area A1, second area A2, and bending area BA of the display panel 10. In order for the electronic device to have bendable characteristics, when the display panel 10 is bent at the bending area BA, the elastic support portion 33 is required to be bent together with the bending area BA of the display panel 10. Therefore, a portion of the support portion 30, corresponding to the bending area BA of the display panel 10, is required to be bendable even when including the first material. To this end, the portion of the support portion 30, corresponding to the bending area BA of the display panel 10, may have a plurality of through holes.

However, in this case, the portion of the support portion 30, corresponding to the bending area BA of the display panel 10, has the plurality of through holes and thus may not effectively support the bending area BA of the display panel 10 when compared to the first area A1 or the second area A2 of the display panel 10. For example, when the bending area BA of the display panel 10 is touched using a tool such as a stylus pen or a user's finger while the user uses the electronic device, and repeated impacts are applied to the bending area BA of the display panel 10, the bending area BA of the display panel 10 may be damaged, or unlike the first area A1 or the second area A2, the bending area BA of the display panel 10 may be recessed toward the support portion 30.

In the electronic device according to some embodiments, as described above, not only the first area A1 and the second area A2 of the display panel 10 but also the bending area BA may be sufficiently supported by the support portion 30. Therefore, even when the bending area BA of the display panel 10 is touched using a tool such as a stylus pen or a user's finger while the user uses the electronic device, and repeated impacts are applied to the bending area BA of the display panel 10, the bending area BA of the display panel 10 may be sufficiently supported by the elastic support portion 33.

Meanwhile, according to some embodiments, other components may be arranged on the display panel 10 arranged on the support portion 30, as shown in FIG. 2. For example, as shown in FIG. 2, a damping layer 11 may be arranged on the display panel 10, a cover window 13 may be arranged on the damping layer 11, and a protective layer 15 may be arranged on the cover window 13. As necessary, a PSA layer may be arranged between the display panel 10 and the damping layer 11, between the damping layer 11 and the cover window 13, and between the cover window 13 and the protective layer 15, enabling them to be bonded to each other.

The electronic device may further include a camera, a sensor, a battery, a printed circuit board, a driving chip, a main processor, a memory, and/or a communication module, according to some embodiments. These additional components may be arranged under the support portion 30. The electronic device may include a case that may be coupled with the display panel 10 and forms the overall lower exterior of the electronic device, wherein the case may accommodate the additional components within a space between the case and the support portion 30. Descriptions of some of the additional components may be omitted for convenience of description.

The cover window 13 may be arranged above the display panel 10 to cover a top surface (in the +z direction) of the display panel 10. The cover window 13 may function to protect the top surface of the display panel 10. The cover window 13 may include light-transmissive resin or glass. When the cover window 13 includes glass, the cover window 13 may be bent at a portion corresponding to the bending area BA of the display panel 10, by including ultra-thin glass. The cover window 13 may include, as necessary, a transmissive portion corresponding to a display area of the display panel 10, and a light-blocking portion surrounding the transmissive portion. The light-blocking portion may include an opaque material (for example, a colored opaque material) that blocks light.

The damping layer 11 may be arranged between the display panel 10 and the cover window 13 to reduce the amount of impact transmitted to the display panel 10 by absorbing at least a portion of the impact transmitted from the outside via the cover window 13. The damping layer 11 may include light-transmissive polymer resin such as polyethylene terephthalate.

The protective layer 15 may be arranged on the cover window 13, thereby preventing, reducing, or minimizing damage to the cover window 13 caused by external impacts. The protective layer 15 may include light-transmissive polymer resin such as polyethylene terephthalate.

The electronic device according to some embodiments may include a stacked structure in which various layers, such as the damping layer 11, the cover window 13, and the protective layer 15 as well as the display panel 10 and the support portion 30, are stacked. In addition, the stacked structure may be bent in the same manner as the display panel 10 when the display panel 10 is bent at the bending area BA.

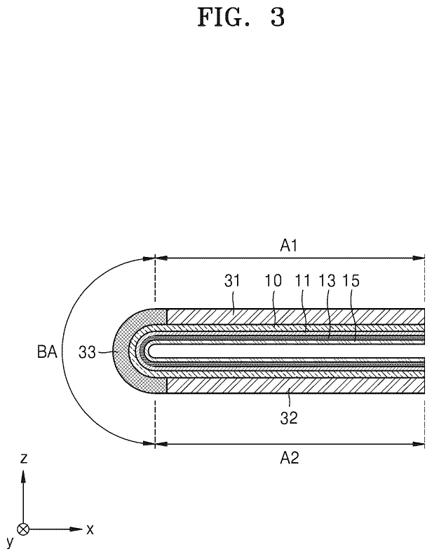

FIG. 3 is a cross-sectional view schematically illustrating the electronic device of FIG. 2 when bent as described above. As described above, among the front surface and rear surface of the display panel 10, the front surface is the display surface. The electronic device according to some embodiments may be an in-folding-type electronic device in which the front surface of the display panel 10, which is a display surface, is arranged on the inside as shown in FIG. 3 when the electronic device is bent. Accordingly, the support portion 30 may be bent together with the display panel 10 at the back of the display panel 10. In detail, the support portion 30 may be bent at the elastic support portion 33 and be bent together with the display panel 10. In this case, because the elastic support portion 33 of the support portion 30 has elasticity, a portion of the elastic support portion 33 may be elongated and bent.

If the support portion 30 does not include the elastic support portion 33, when the support portion 30 is bent, the support portion 30 may not be sufficiently elongated at a bent portion. In this case, when the electronic device is bent as shown in FIG. 3, the first area A1 and the second area A2 of the display panel 10 which is most closely bonded to the support portion 30 may be pulled toward the bending area BA. This is because the display panel 10 is affected by the support portion 30 that is not sufficiently elongated. As a result, the damping layer 11, the cover window 13, and/or the protective layer 15, which are arranged on the front surface of the display panel 10, may slip relative to the display panel 10, such that ends of the damping layer 11, the cover window 13, and/or the protective layer 15 may protrude outside an end of the display panel 10. This may occur because the thickness of the support portion 30 is greater than the thickness of each of the damping layer 11, the cover window 13, and the protective layer 15. When the electronic device returns from a bent state to an unbent state, the ends of the damping layer 11, the cover window 13, and/or the protective layer 15 may be aligned with the end of the display panel 10. When the bending and unbending of the electronic device are repeated, peeling may occur at an interface between the display panel 10, the damping layer 11, the cover window 13, and/or the protective layer 15.

However, in the case of the electronic device according to some embodiments, the support portion 30 includes the elastic support portion 33 as described above, and thus, such problems may be prevented, reduced, or minimized. In the case of the electronic device according to some embodiments, when the support portion 30 is bent, the elastic support portion 33 may be sufficiently elongated. Therefore, when the electronic device is bent, a state in which an end of the first support portion 31 is aligned with an end of the first area A1 of the display panel 10 and an end of the second support portion 32 is aligned with an end of the second area A2 of the display panel 10 may be maintained as shown in FIG. 3. As a result, when the electronic device is bent, the damping layer 11, the cover window 13, and/or the protective layer 15, which are arranged on the front surface of the display panel 10, may be prevented, reduced, or minimized from slipping relative to the display panel 10.

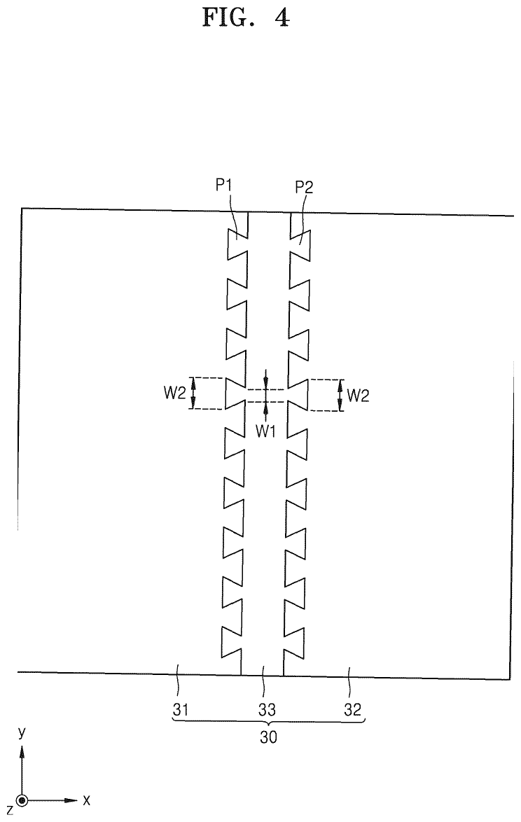

FIG. 4 is a plan view schematically illustrating a portion of an electronic device according to some embodiments, i.e., the support portion 30. As shown in FIG. 4, the elastic support portion 33 of the support portion 30 included in the electronic device according to some embodiments may include a plurality of first protrusions P1 and a plurality of second protrusions P2. The plurality of first protrusions P1 of the elastic support portion 33 may protrude into the first support portion 31, and the plurality of second protrusions P2 of the elastic support portion 33 may protrude into the second support portion 32.

As such, by including the first protrusions P1 protruding into the first support portion 31 and the second protrusions P2 protruding into the second support portion 32, the elastic support portion 33 may be securely coupled with the first support portion 31 and the second support portion 32, thereby preventing, reducing, or minimizing separation between them during use by a user.

In this case, each of the first protrusions P1 may have a portion having a first width W1 and a portion having a second width W2. The second width W2 is greater than the first width W1, and the portion having the second width W2 may be arranged farther from a center of the elastic support portion 33 than the portion having the first width W1. In other words, a portion of the elastic support portion 33, having the second width W2 that is relatively large, may be arranged at an inner portion of the first support portion 31. Accordingly, by increasing the strength of coupling between the elastic support portion 33 and the first support portion 31, separation between the elastic support portion 33 and the first support portion 31 during use by a user may be prevented, reduced, or minimized.

Similarly, each of the second protrusions P2 may also have a portion having the first width W1 and a portion having the second width W2. The second width W2 is greater than the first width W1, and the portion having the second width W2 may be arranged farther from the center of the elastic support portion 33 than the portion having the first width W1. In other words, a portion of the elastic support portion 33, having the second width W2 that is relatively large, may be arranged at an inner portion of the second support portion 32. Accordingly, by increasing the strength of coupling between the elastic support portion 33 and the second support portion 32, separation between the elastic support portion 33 and the second support portion 32 during use by a user may be prevented, reduced, or minimized.

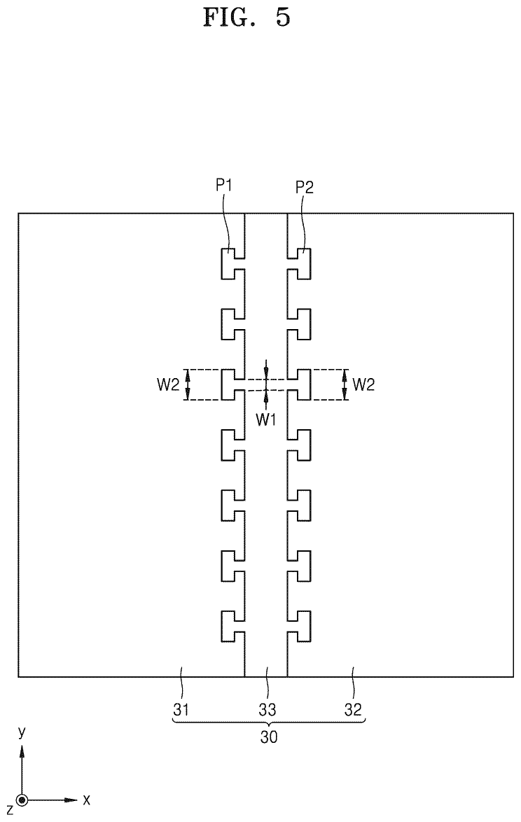

FIG. 4 illustrates that each of the first protrusions P1 and each of the second protrusions P2 have a parallelogram (or a substantially parallelogram) shape, but embodiments according to the present disclosure are not limited thereto. For example, as shown in FIG. 5 which is a plan view schematically illustrating the support portion 30 which is a portion of the electronic device according to some embodiments, each of the first protrusions P1 may have a first-1 portion P1-1 having the first width W1 and a first-2 portion P1-2 having the second width W2. The second width W2 is greater than the first width W1, and the first-2 portion P1-2 having the second width W2 may be arranged farther from the center of the elastic support portion 33 than the first-1 portion P1-1 having the first width W1. In other words, the first-2 portion P1-2 having the second width W2 which is relatively large may be arranged at the inner portion of the first support portion 31 than the first-1 portion P1-1. Each of the first-1 portion P1-1 and the first-2 portion P1-2 may have a polygonal shape in a plan view. FIG. 5 illustrates that each of the first-1 portion P1-1 and the first-2 portion P1-2 has a rectangular shape in a plan view. Accordingly, by increasing the strength of coupling between the elastic support portion 33 and the first support portion 31, separation between the elastic support portion 33 and the first support portion 31 during use by a user may be prevented, reduced, or minimized.

Similarly, each of the second protrusions P2 may have a second-1 portion P2-1 having the first width W1 and a second-2 portion P2-2 having the second width W2. The second width W2 is greater than the first width W1, and the second-2 portion P2-2 having the second width W2 may be arranged farther from the center of the elastic support portion 33 than the second-1 portion P2-1 having the first width W1. In other words, the second-2 portion P2-2 having the second width W2 which is relatively large may be arranged at the inner portion of the first support portion 31 than the second-1 portion P2-1. Each of the second-1 portion P2-1 and the second-2 portion P2-2 may have a polygonal shape in a plan view. FIG. 5 illustrates that each of the second-1 portion P2-1 and the second-2 portion P2-2 has a rectangular shape in a plan view. Accordingly, by increasing the strength of coupling between the elastic support portion 33 and the second support portion 32, separation between the elastic support portion 33 and the second support portion 32 during use by a user may be prevented, reduced, or minimized.

The first protrusions P1 and the second protrusions P2 of the elastic support portion 33 may be arranged to correspond to each other as shown in FIGS. 4 and 5. For example, positions of the first protrusions P1 and positions of the second protrusions P2 may be the same in the second direction (the y-axis direction) in which the bending area BA of the display panel 10 and the elastic support portion 33 extend. However, in this case, when the electronic device is bent, a tensile force applied to a portion where the first protrusions P1 and the second protrusions P2 of the elastic support portion 33 are present may be different from a tensile force applied to a portion where the first protrusions P1 and the second protrusions P2 of the elastic support portion 33 are not present, and thus, significant stress may be applied to the elastic support portion 33.

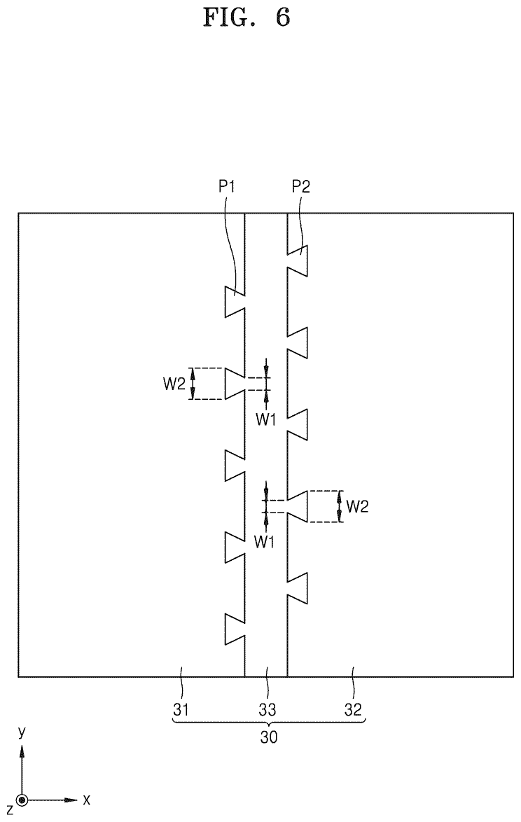

Therefore, in consideration of the above, as shown in FIG. 6 which is a plan view schematically illustrating the support portion 30 which is a portion of the electronic device according to some embodiments, the first protrusions P1 and the second protrusions P2 may be alternately arranged relative to each other in the second direction (the y-axis direction) in which the bending area BA of the display panel 10 and the elastic support portion 33 extend. Accordingly, when the electronic device is bent, a uniform (or substantially uniform) tensile force may be applied to various points of the elastic support portion 33.

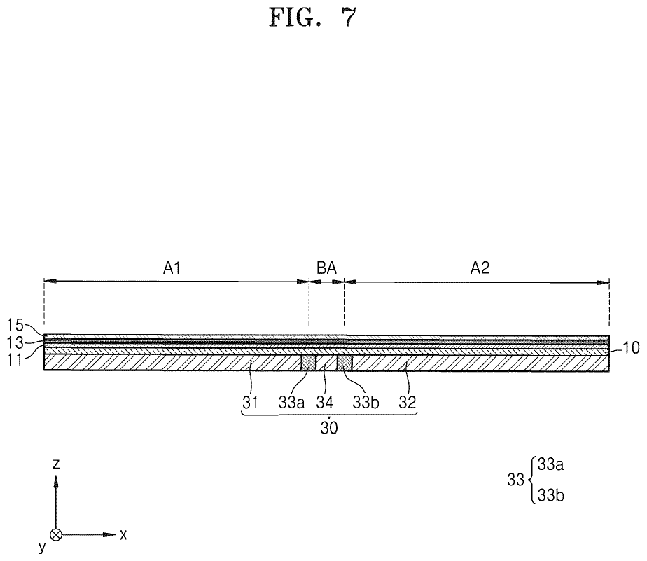

FIG. 7 is a cross-sectional view schematically illustrating a portion of an electronic device according to some embodiments. As shown in FIG. 7, the elastic support portion 33 included in the support portion 30 may include a first elastic support portion 33a and a second elastic support portion 33b. The first elastic support portion 33a may be in contact with the first support portion 31, and the second elastic support portion 33b may be in contact with the second support portion 32. In addition, the support portion 30 may further include an auxiliary support portion 34 arranged between the first elastic support portion 33a and the second elastic support portion 33b. The auxiliary support portion 34 may include the same first material as the first support portion 31 and the second support portion 32. In addition, the auxiliary support portion 34 may be in contact with each of the first elastic support portion 33a and the second elastic support portion 33b.

When the electronic device is bent, the support portion 30 is not required to be elongated over the entire portion of the support portion 30 that corresponds to the bending area BA of the display panel 10. Therefore, by having the auxiliary support portion 34, which includes the same first material as the first support portion 31 and the second support portion 32, arranged in a portion of the support portion 30 corresponding to the bending area BA of the display panel 10, a portion of the bending area BA of the display panel 10 may be sufficiently supported by the auxiliary support portion 34, and by having the elastic support portion 33, which is included in the support portion 30, include the first elastic support portion 33a and the second elastic support portion 33b, the support portion 30 may be sufficiently elongated at a necessary portion when the display panel 10 is bent.

In this case, in a plan view, a boundary between the first area A1 and the bending area BA of the display panel 10 may be arranged within the first elastic support portion 33a, and a boundary between the second area A2 and the bending area BA of the display panel 10 may be arranged within the second elastic support portion 33b. Accordingly, while ensuring that a portion of the bending area BA of the display panel 10 is sufficiently supported by the auxiliary support portion 34, the support portion 30 may be elongated at the first elastic support portion 33a and the second elastic support portion 33b when the electronic device is bent, thereby reducing occurrence of stress within the support portion 30 and occurrence of stress applied to the display panel 10.

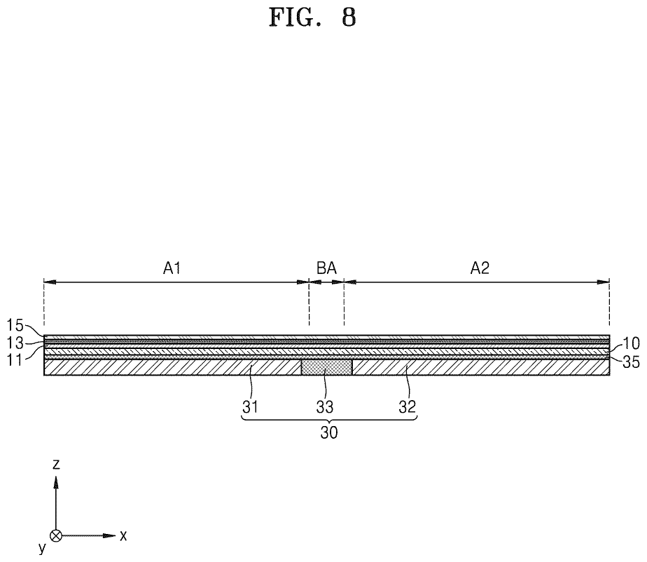

FIG. 8 is a cross-sectional view schematically illustrating a portion of an electronic device according to some embodiments. As shown in FIG. 8, the electronic device may further include an additional support portion 35 arranged between the display panel 10 and the support portion 30. The additional support portion 35 may entirely cover a bottom surface of the display panel 10, that is, may entirely cover the rear surface of the display panel 10. The additional support portion 35 may include the same second material as the elastic support portion 33.

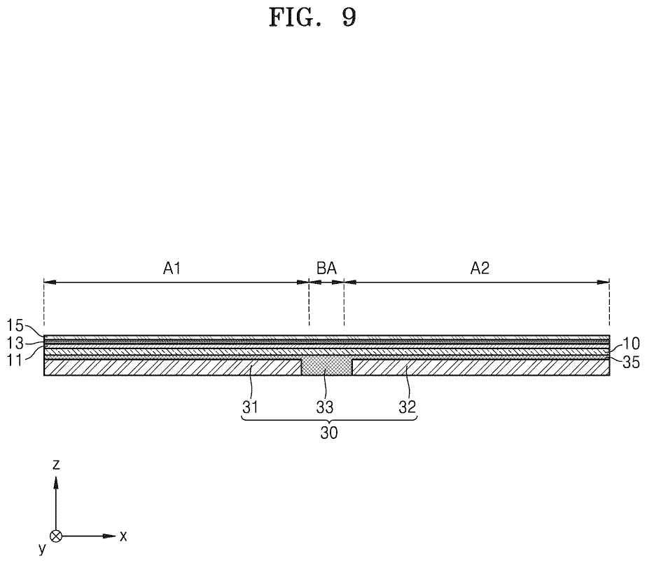

As such, by having the electronic device include the additional support portion 35 including the second material with high elasticity between the display panel 10 and the support portion 30, the amount of stress that may occur in the display panel 10, etc. when the electronic device is bent may be significantly reduced. In addition, even when the bending area BA of the display panel 10 is touched using a tool such as a stylus pen or a user's finger while the user uses the electronic device, and repeated impacts are applied to the bending area BA of the display panel 10, damage to the bending area BA of the display panel 10 may be effectively prevented, reduced, or minimized by transmitting the impact not only to the elastic support portion 33 of the support portion 30 but also to the first support portion 31 and the second support portion 32 via the additional support portion 35. Furthermore, as shown in FIG. 9 which is a cross-sectional view schematically illustrating a portion of the electronic device according to some embodiments, the elastic support portion 33 of the support portion 30 and the additional support portion 35 may be integrally formed as a single body.

As described above, an electronic device 1 of the disclosure may be various types of devices. FIG. 10 is a block diagram schematically illustrating the electronic device 1 according to some embodiments. The electronic device 1 according to some embodiments may be a display device, and may further include a module having additional functions, in addition to a display module 53.

As shown in FIG. 10, the electronic device 1 according to some embodiments may include a processor 51, a memory 52, the display module 53, a power module 54, an input module 55, an output module 56, and a communication module 57.

The display module 53 may include the display panel 10 as described above. For example, the display module 53 may include the display panel 10 and a data driver mounted thereon.

The processor 51 may control most of the components of the electronic device 1. For example, the processor 51 may output digital video data to the display module 53 such that the display module 53 may display an image, and may receive input data from the input module 55 such that a function according to the corresponding data is performed in the electronic device 1. The processor 51 may include at least one of a central processing unit (CPU), an application processor (AP), a graphics processing unit (GPU), a communication processor (CP), an image signal processor (ISP), or a controller.

As necessary, the processor 51 may be divided into two or more from a functional or structural point of view. For example, the processor 51 may include a main processor in the form of a first driving chip including a CPU, and an auxiliary processor in the form of a second driving chip as part of the display module 53. The auxiliary processor in the form of a second driving chip may include a controller that receives an image signal from the main processor and processes the image signal to satisfy interface specifications of the display panel 10 included in the display module 53.

The memory 52 may include at least one of non-volatile memory or volatile memory. The memory 52 may store data information required to operate the processor 51 or the display module 53. When the processor 51 executes an application stored in the memory 52, a data signal and/or an input control signal for an image may be transmitted to the display module 53, and the display module 53 may output image information by processing the received signal.

The power module 54 may include a power supply module, such as a power adapter or a battery device, and a power conversion module that converts power supplied by the power supply module to generate power required to operate the electronic device 1. The power conversion caused by the power conversion module may include DC-DC conversion, AC-DC conversion, and DC-AC conversion. Embodiments according to the present disclosure are not limited thereto.

The input module 55 may provide input information to the processor 51 and/or the display module 53. The input module 55 may include a physical button, a keyboard, a microphone, and various sensor modules. Examples of a sensor modules may include a touch sensor, a pressure sensor, a distance sensor, a location sensor, a digitizer, a motion recognition sensor, a camera sensor, a light-receiving sensor, a photoelectric conversion sensor, and/or a temperature sensor. In addition, the sensor module may include a biometric sensor such as a blood pressure sensor, a blood glucose sensor, an electrocardiogram sensor, and/or a heart rate sensor.

The output module 56 may receive information in addition to an image received from the processor 51, and provide the information to a user. The output module 56 may include, for example, a sound module, a haptic module, and/or a light-emitting module. In addition, the output module 56 may include a functional module unique to the electronic device 1, such as a cooling module of a refrigerators.

For reference, the display module 53 may also perform an output function. For example, the display panel 10 included in the display module 53 may display (output) information processed by the electronic device 1. For example, the display panel 10 may display execution screen information of an application running on the electronic device 1, display a user interface (UI) according to the execution screen information, or display graphical user interface (GUI) information. The display panel 10 may include a display layer that displays an image, and a touch screen layer that detects a user's touch input. Accordingly, the display panel 10 may function as part of the input module 55 that provides an input interface between the electronic device 1 and a user, and at the same time, may function as part of the output module 56 that provides an output interface between the electronic device 1 and the user.

The communication module 57 is responsible for transmission/reception of information between the electronic device 1 and an external device, and may include a reception unit and a transmission unit. The communication module 57 may include various wireless communication modules, such as a mobile communication module, a broadcast reception module, a wireless Internet module, a short-range communication module, a Wi-Fi module, and/or a Bluetooth module, or may include various wired communication modules.

The electronic device 1 shown in FIG. 10 is merely an example, and for example, a display device that does not have a communication function may not include the communication module 57. In addition, for example, when the electronic device 1 includes a display device, at least one of the components of the electronic device 1 may be included in the display device. In addition, some individual modules functionally included in one module may be included in a display device, while some others may be included in the electronic device 1, separate from the display device. For example, the display device includes the display module 53, and the processor 51, the memory 52, and the power module 54 may be components of the electronic device 1 rather than the display device. Alternatively, the display device includes the display module 53 and the power module 54 and may be modified in various ways such as a case where the power module 54 may supply power to components such as the processor 51 and the memory 52 of the electronic device 1.

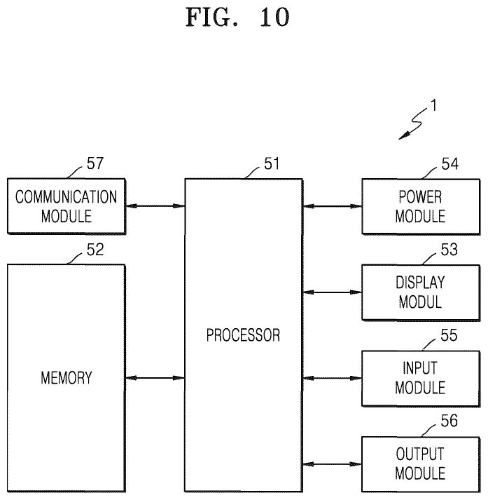

FIG. 11 shows schematic views schematically illustrating various types of the electronic device 1 according to embodiments. FIG. 11 illustrates, as examples of the electronic device 1, a smartphone 1_1a, a tablet PC 1_1b, a laptop 1_1c, a TV 1_1d, and a desk monitor 1_1e.

The smartphone 1_1a may include not only the processor 51, the memory 52, the display module 53, and the power module 54, but also the input module 55, such as a touch sensor, and the communication module 57. The smartphone 1_1a may process information received via the communication module 57 or another input module to display the information via the display module 53.

Similar to the smartphone 1_1a, the tablet PC 1_1b, the laptop 1_1c, the TV 1_1d, and/or the desk monitor 1_1e may include the display module 53 and the input module 55, and in some cases, may also include the communication module 57.

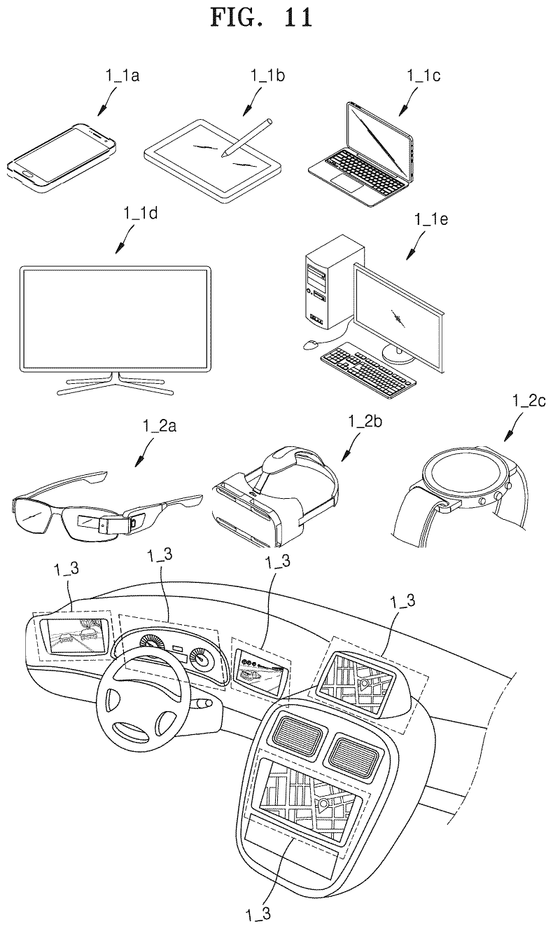

FIG. 12 show schematic views schematically illustrating a case where various types of the electronic device 1 according to embodiments are wearable electronic devices. FIG. 12 illustrates, as examples of the electronic device 1, smart glasses 1_2a, a head-mounted display 1_2b, and a smart watch 1_2c.

The smart glasses 1_2a and the head-mounted display 1_2b may include the display module 53 that display an image, and a reflector that reflects light from a display surface of the display module 53 and provides the image to a user's eyes. The user may experience virtual reality or augmented reality by using the electronic device 1.

The smart watch 1_2c includes a biometric sensor as the input module 55, and may provide biometric information recognized via the biometric sensor to a user via the display module 53.

FIG. 13 is a schematic view schematically illustrating a case where the electronic device 1 according to some embodiments is a vehicle electronic device 1_3. As shown in FIG. 13, the vehicle electronic device 1_3 may be included in an instrument panel or center fascia of a vehicle, or may be a center information display (CID) arranged on a dashboard of a vehicle or a room mirror display in lieu of a side-view mirror.

The electronic device 1 according to some embodiments of the present disclosure is not limited thereto. For example, the electronic device 1 according to some embodiments may include not only devices primarily focused on displays, such as billboards, digital signage, and/or game consoles, but also various home appliances that display information via the display module 53, such as refrigerators, washing machines, dryers, air conditionals, and/or robot vacuum cleaners. In addition, when the display module 53 has a function of transmitting light, the electronic device 1 may be a smart window or a transparent display device that displays a background and a display image together. The electronic device 1 according to some embodiments of the present disclosure is not limited thereto, and any electronic device 1 that includes the display panel 10 may fall within the scope of the disclosure.

According to some embodiments as described above, an electronic device having excellent impact resistance against external impacts may be implemented. However, the scope of embodiments according to the present disclosure are not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. An electronic device comprising:
a display panel comprising a first area, a second area, and a bending area between the first area and the second area, the bending area being bendable and having a shape extending in a second direction intersecting a first imaginary straight line extending in a first direction connecting the first area and the second area to each other; and
a support portion located at a back of the display panel, and comprising a first support portion supporting the first area and comprising a first material, a second support portion supporting the second area and comprising the first material, and an elastic support portion supporting at least a portion of the bending area and comprising a second material having elasticity greater than elasticity of the first material.

2. The electronic device of claim 1, wherein the elastic support portion connects the first support portion and the second support portion to each other.

3. The electronic device of claim 2, wherein, in a plan view, an area of the elastic support portion is greater than an area of the bending area.

4. The electronic device of claim 2, wherein, in a plan view, the bending area is within the elastic support portion.

5. The electronic device of claim 1, wherein, in a plan view, the elastic support portion has a plurality of first protrusions protruding into the first support portion and a plurality of second protrusions protruding into the second support portion.

6. The electronic device of claim 5, wherein, in the plan view, each of the plurality of first protrusions comprises a first-1 portion having a first width and a first-2 portion having a second width greater than the first width, and the first-2 portion is located farther from a center of the elastic support portion than the first-1 portion.

7. The electronic device of claim 5, wherein, in the plan view, each of the plurality of second protrusions comprises a second-1 portion having a first width and a second-2 portion having a second width greater than the first width, and the second-2 portion is located farther from a center of the elastic support portion than the second-1 portion.

8. The electronic device of claim 5, wherein the plurality of first protrusions and the plurality of second protrusions are alternately arranged in the second direction.

9. The electronic device of claim 1, wherein the elastic support portion comprises a first elastic support portion in contact with the first support portion and a second elastic support portion in contact with the second support portion, and the support portion further comprises an auxiliary support portion comprising the first material and arranged between the first elastic support portion and the second elastic support portion.

10. The electronic device of claim 9, wherein the auxiliary support portion is in contact with each of the first elastic support portion and the second elastic support portion.

11. The electronic device of claim 9, wherein, in a plan view, a boundary between the first area and the bending area is within the first elastic support portion, and a boundary between the second area and the bending area is within the second elastic support portion.

12. The electronic device of claim 1, further comprising an additional support portion between the display panel and the support portion.

13. The electronic device of claim 12, wherein the additional support portion entirely covers a bottom surface of the display panel.

14. The electronic device of claim 12, wherein the elastic support portion and the additional support portion are integrally formed as a single body.

15. The electronic device of claim 1, wherein the first material comprises metal, carbon fiber-reinforced plastic (CFRP), or glass fiber-reinforced plastic (GFRP).

16. The electronic device of claim 1, wherein the second material comprises rubber resin, silicone resin, or thermoplastic polyurethane (TPU).

17. The electronic device of claim 1, wherein the electronic device is one of a flat panel display, a curved display, a computer monitor, a medical monitor, a television, an advertisement board, an indoor light, an outdoor light, and/or a signal light, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual reality display, an augmented reality display, a vehicle, a video wall comprising multiple displays tiled together, a theater screen, a stadium screen, a phototherapy device, or a signboard.
